(19) United States
(12) Patent Application Publication
(10) Pub. No.: US 2026/0347375 A1
(43) Pub. Date: Nov. 5, 2026

(54) PREPARATION OF METAL COMPLEX, METAL COMPLEX, RESIST COMPOSITION, LAMINATE, AND PATTERN FORMING PROCESS

(71) Applicant: SHIN-ETSU CHEMICAL CO., LTD., Tokyo (JP)

(72) Inventors: Satoshi Kusama, Joetsu-shi (JP); Ryo Nishikawa, Joetsu-shi (JP); Kousuke Ohyama, Joetsu-shi (JP)

(73) Assignee: SHIN-ETSU CHEMICAL CO., LTD., Tokyo (JP)

(21) Appl. No.: 19/643,291

(22) Filed: Apr. 9, 2026

(30) Foreign Application Priority Data
Apr. 22, 2025 (JP) 2025-070498

(51) Int. Cl. C07F 3/06; G03F 7/004; G03F 7/20

(52) U.S. Cl. CPC C07F 3/06; G03F 7/0043; G03F 7/2059; G03F 7/0045

(57) ABSTRACT

A high-purity metal complex is prepared by step (i) of mixing a raw metal complex containing impurities with water and an organic solvent, and step (ii) of filtering insolubles out of the mixture to remove the impurities. A resist composition comprising the metal complex is stable and easy to handle and exhibits high sensitivity, high resolution and reduced LWR when processed by EB and EUV lithography.

### CROSS-REFERENCE TO RELATED APPLICATION

This non-provisional application claims priority under 35 U.S.C. § 119(a) on Patent Application No. 2025-070498 filed in Japan on Apr. 22, 2025, the entire contents of which are hereby incorporated by reference.

### TECHNICAL FIELD

This invention relates to a method for preparing a metal complex, metal complex, resist composition, laminate, and pattern forming process.

### BACKGROUND ART

While a higher integration density, higher operating speed and lower power consumption of LSIs are demanded to comply with the expanding IoT market, the effort to reduce the pattern rule is in rapid progress. The wide-spreading logic device market drives forward the miniaturization technology. As the advanced miniaturization technology, microelectronic devices of 10-nm node are manufactured in a mass scale by the double, triple or quadro-patterning version of the immersion ArF lithography. Active research efforts have been made on the manufacture of 7-nm node devices by the next generation EUV lithography of wavelength 13.5 nm.

As the feature size is reduced, image blurs due to acid diffusion become a problem (see Non-Patent Document 1). To insure resolution for fine patterns with a feature size of 45 nm et seq., not only an improvement in dissolution contrast is requisite as discussed in the prior art, but the control of acid diffusion is also important (see Non-Patent Document 2). Since chemically amplified resist compositions are designed such that sensitivity and contrast are enhanced by acid diffusion, an attempt to minimize acid diffusion by reducing the temperature and/or time of post-exposure bake (PEB) fails, resulting in drastic reductions of sensitivity and contrast.

Addition of an acid generator capable of generating a bulky acid is effective for suppressing acid diffusion. It is then proposed to copolymerize a polymer with an acid generator in the form of an onium salt having a polymerizable olefin. With respect to the patterning of a resist film to a feature size of 16 nm et seq., it is believed impossible in the light of acid diffusion to form such a pattern from a chemically amplified resist composition.

It would be desirable to have a non-chemically-amplified resist composition.

A typical non-chemically-amplified resist material is polymethyl methacrylate (PMMA). It is a positive resist material which increases solubility in organic solvent developer through the mechanism that the molecular weight becomes lower as a result of scission of the main chain upon EB or EUV exposure. Because of the lack of a cyclic structure, there remain drawbacks like poor etch resistance and noticeable outgassing during exposure.

Hydrogensilsesquioxane (HSQ) is a material for a negative resist composition which turns insoluble in alkaline developer through crosslinking by condensation reaction of silanol generated upon EB or EUV exposure. Also chlorine-substituted calixarene functions as a material for a negative resist composition. Since these materials have a small molecular size prior to crosslinking and avoid any image blur due to acid diffusion, they exhibit reduced edge roughness and very high resolution. They are thus used as a pattern transfer material for representing the resolution limit of the exposure tool.

However, these materials are insufficient in sensitivity, with further improvements being needed.

One of the causes that retard the development of EUV lithography materials is a small number of photons available with EUV exposure. The energy of EUV is extremely higher than that of ArF excimer laser. The number of photons available with EUV exposure is 1/14 of the number by ArF exposure. The size of pattern features formed by the EUV lithography is less than half the size by the ArF lithography. Therefore, the EUV lithography is quite sensitive to a variation of photon number. A variation in the number of photons in the radiation region of extremely short wavelength is shot noise as a physical phenomenon. It is impossible to eliminate the influence of shot noise. Attention is thus paid to stochastics. While it is impossible to eliminate the influence of shot noise, discussions are held how to reduce the influence. There is observed a phenomenon that under the influence of shot noise, values of CDU and LWR are increased and holes are blocked at a probability of one several millionth. The blockage of holes leads to electric conduction failure to prevent transistors from operation, adversely affecting the performance of an overall device.

As the means for reducing the influence of shot noise on the resist side, Patent Document 1 discloses an inorganic resist composition containing a highly EUV-absorbing element as nucleus. Although the inorganic resist composition has a relatively high sensitivity, it is still unsatisfactory in many aspects including solubility in resist solvents, storage stability, and defectiveness.

Non-Patent Document 3 discloses a negative tone resist composition comprising a zinc compound. This non-chemically-amplified resist composition based on zinc element having high EUV absorption is improved in stochastics and achieves a high sensitivity and high resolution, but it suffers from problems including low stability due to degradation of components and resist film after film formation by airborne moisture, and difficult reproducibility of lithography due to variations of performance among manufacture batches.

### CITATION LIST

Patent Document 1: JP-A 2015-108781
Non-Patent Document 1: SPIE Vol. 5039 p1(2003)
Non-Patent Document 2: SPIE Vol. 6520 p65203L-1 (2007)
Non-Patent Document 3: J. Micro/Nanolith. MEMS MOEMS Vol. 18 p043504 (2019)

### SUMMARY OF THE INVENTION

An object of the invention is to provide a resist composition which is stable during storage and easy to handle and exhibits a satisfactory sensitivity, resolution and LWR when processed by photolithography using high-energy radiation, typically EB and EUV lithography, a metal complex for use in the resist composition, a method for preparing the metal complex, and a patterning process using the resist composition.

The inventors have found that a resist composition based on a specific metal complex is stable, forms a resist film exhibiting a high sensitivity, improved resolution and reduced LWR, and is improved in reproducibility of lithography. The composition is thus quite useful in precise micropatterning.

In one aspect, the invention provides a method for preparing a high-purity metal complex comprising the steps of:
(i) mixing a raw metal complex with water and an organic solvent, the raw metal complex containing an impurity, and
(ii) filtering insolubles out of the mixture of step (i) to remove at least part of the impurity.

In a preferred embodiment, the raw metal complex is a zinc tetranuclear cluster having the formula (1):

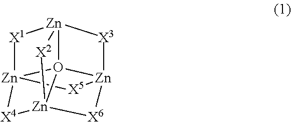

wherein X¹, X², X³, X⁴, X⁵ and X⁶ are each independently a ligand having the formula (1a) or (1b):

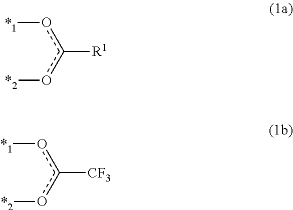

wherein R¹ is hydrogen, carbonyl or a C₁-C₂₀ hydrocarbyl group which may contain a heteroatom, exclusive of trifluoromethyl, *1 and *2 each designate a point of attachment to zinc atom.

In a more preferred embodiment, the raw metal complex is a zinc tetranuclear cluster having the formula (1) wherein the content of the ligand having formula (1b) is more than 5 mol % based on the overall ligands.

In a more preferred embodiment, the high-purity metal complex is a zinc tetranuclear cluster having the formula (1) wherein the content of the ligand having formula (1b) is not more than 5 mol % based on the overall ligands.

In another aspect, the invention provides a high-purity metal complex which is a zinc tetranuclear cluster having formula (1) defined above, wherein the content of the ligand having formula (1b) is not more than 5 mol % based on the overall ligands.

In a further aspect, the invention provides a resist composition comprising the high-purity metal complex defined above and a solvent.

In a still further aspect, the invention provides a laminate comprising a substrate and a resist film formed on the substrate from the resist composition defined above.

The laminate may further comprise a resist underlying film between the substrate and the resist film.

In a yet further aspect, the invention provides a process for forming a pattern, comprising the steps of applying the resist composition defined above onto a substrate to form a resist film, exposing the resist film to high-energy radiation, and developing the exposed resist film to form a resist pattern.

Typically, the high-energy radiation is EB or EUV.

### Advantageous Effects of the Invention

The preparation method of the invention is successful in obtaining a high-purity metal complex by selectively removing a metal complex impurity having a moisture-sensitive ligand. Since the high-purity metal complex thus obtained contains no or little metal complex having a moisture-sensitive ligand, it has high storage stability in the ambient atmosphere. Because of the high purity, the high-purity metal complex is characterized by a minimal difference in compositional ratio between batches and improved reproducibility in lithography. A resist composition comprising the metal complex exhibits both high sensitivity and resolution and reduced LWR when processed by EB and EUV lithography processes and is improved in stability and lithography reproducibility. The resist composition is quite useful in micropatterning.

### BRIEF DESCRIPTION OF DRAWING

FIG. 1 is a diagram showing the peak intensity of —CF₃ group, as analyzed by ¹⁹F-NMR spectroscopy, in raw metal complex IM-3 prepared in Example 1-3 and high-purity metal complex Z-3 prepared in Example 2-3.

### DESCRIPTION OF THE PREFERRED EMBODIMENT

As used herein, the notation (Cn-Cm) means a group containing from n to m carbon atoms per group. In chemical formulae, Me stands for methyl. The abbreviations and acronyms have the following meaning.
EB: electron beam
EUV: extreme ultraviolet
PEB: post-exposure bake
PAG: photoacid generator
LWR: line width roughness
CD: critical dimension
CDU: critical dimension uniformity

### [Preparation of High-Purity Metal Complex]

The invention provides a method for preparing a high-purity metal complex comprising the steps of (i) mixing a raw metal complex with water and an organic solvent, the raw metal complex containing an impurity, and (ii) filtering insolubles out of the mixture of step (i) to remove at least part of the impurity.

### Step (i)

Step (i) is to mix a raw metal complex with water and an organic solvent.

The raw metal complex is not particularly limited as long as it is a metal complex composed of metal atoms and ligands of at least two types. When the inventive method is applied to such a raw metal complex, a metal complex having a moisture-sensitive ligand is selectively removed due to a difference in the reactivity of ligands with water. Thus a high-purity metal complex having an increased content of the desired ligand is obtained.

The preferred raw metal complex is a zinc tetranuclear cluster having the formula (1).

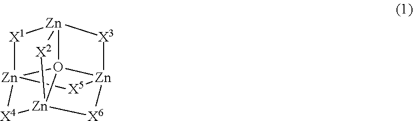

In formula (1), X¹, X², X³, X⁴, X⁵ and X⁶ are each independently a ligand having the formula (1a) or (1b), which is also referred to as ligand (1a) or (1b).

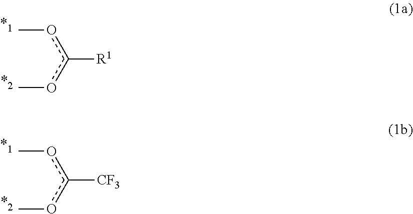

In formula (1a), R¹ is hydrogen, carbonyl or a C₁-C₂₀ hydrocarbyl group which may contain a heteroatom, exclusive of trifluoromethyl, and *1 and *2 each designate a point of attachment to zinc atom.

The hydrocarbyl group may be saturated or unsaturated and straight, branched or cyclic. Examples thereof include C₁-C₂₀ alkyl groups such as methyl, ethyl, n-propyl, isopropyl, n-butyl, isobutyl, sec-butyl, tert-butyl, n-pentyl, tert-pentyl, n-hexyl, n-octyl, 2-ethylhexyl, n-nonyl, and n-decyl; C₃-C₂₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, tricyclo[5.2.1.0^{2,6}]decyl, adamantyl, and adamantylmethyl; C₂-C₂₀ alkenyl groups such as vinyl and 2-propenyl; C₆-C₂₀ aryl groups such as phenyl and naphthyl, and combinations thereof. In the hydrocarbyl group, some or all hydrogen may be substituted by a moiety containing a heteroatom such as oxygen, sulfur, nitrogen or halogen, and some constituent —CH₂— may be replaced by a moiety containing a heteroatom such as oxygen, sulfur or nitrogen, so that the group may contain a hydroxy moiety, cyano moiety, halogen, carbonyl moiety, ether bond, thioether bond, ester bond, sulfonate ester bond, carbonate bond, carbamate bond, lactone ring, sultone ring, or carboxylic anhydride (—C(═O)—O—C(═O)—) moiety. Preferably R¹ is fluorine-free. When a plurality of ligands (1a) are contained, a plurality of R¹ may be identical or different.

Examples of ligand (1a) are shown below, but not limited thereto.

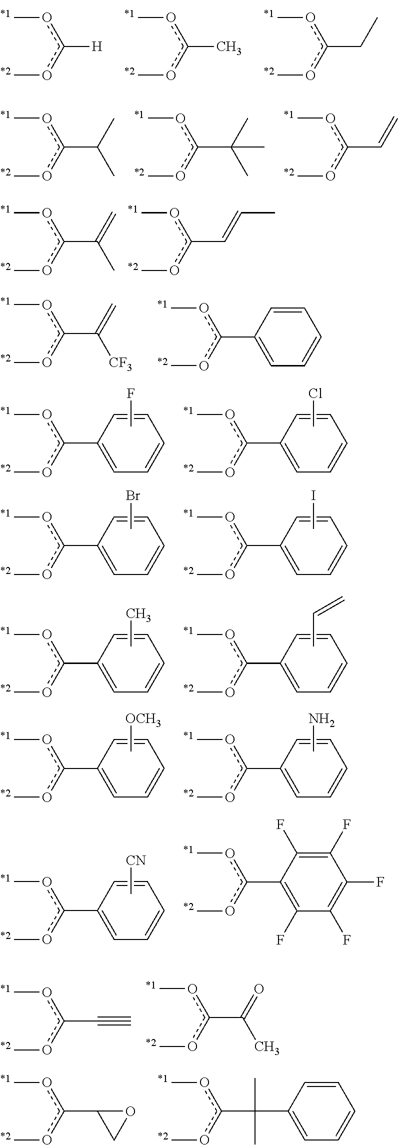

When the raw metal complex contains isomers due to the arrangement of ligands, a mixture of isomers or a single isomer may be used. The raw metal complex used herein may be a single metal complex having a completely controlled proportion of ligands or a mixture of metal complexes having a different proportion of ligands.

In the raw metal complex, the content of ligand (1b) is preferably 1 to 99 mol %, more preferably 5 to 99 mol %, even more preferably 10 to 99 mol %, further preferably 20 to 99 mol %, most preferably 30 to 99 mol % of the overall ligands.

The raw metal complex having formula (1) is obtainable by any well-known method. For example, it may be obtained from ligand substitution reaction of ZnTAC24®, which is commercially available from Takasago International Corp., with a carboxylic acid derivative.

For the synthesis method, reference should be made to J. Micro/Nanolith. MEMS MOEMS Vol. 18 p043504 (2019).

The water used herein may be pure water, tap water, or an aqueous solution containing any solute, with pure water being preferred. The pure water may be water as distilled, filtered or ion exchanged to a higher purity.

The amount of water added is preferably 0.001 to 500 mol %, more preferably 0.001 to 200 mol %, even more preferably 0.001 to 100 mol %, most more preferably 0.01 to 100 mol % based on the raw metal complex, though not particularly limited.

The organic solvent used herein is not particularly limited as long as the raw metal complex is dissolvable therein. Exemplary organic solvents include hydrocarbons such as pentane, hexane, octane, cyclopentane, and cyclohexane; ketones such as cyclohexanone and methyl-2-n-pentyl ketone; alcohols such as 3-methoxybutanol, 3-methyl-3-methoxybutanol, 1-methoxy-2-propanol, 1-ethoxy-2-propanol, and diacetone alcohol; ethers such as isopropyl ether, propylene glycol monomethyl ether, ethylene glycol monomethyl ether, propylene glycol monoethyl ether, ethylene glycol monoethyl ether, propylene glycol dimethyl ether, diethylene glycol dimethyl ether, diethyl ether, tetrahydrofuran, and dioxane; esters such as propylene glycol monomethyl ether acetate, propylene glycol monoethyl ether acetate, ethyl lactate, ethyl pyruvate, butyl acetate, methyl 3-methoxypropionate, ethyl 3-ethoxypropionate, methyl 2-hydroxyisobutyrate, tert-butyl acetate, cyclohexyl acetate, tert-butyl propionate, and propylene glycol mono-tert-butyl ether acetate; lactones such as γ-butyrolactone; carboxylic acids such as acetic acid and propionic acid; aromatic solvents such as benzene, toluene, xylene, cresol, anisole, and benzotrifluoride; halogenated hydrocarbons such as dichloromethane, chloroform, and carbon tetrachloride; and mixtures thereof.

The vessel used in step (i) is not particularly limited as long as it can contain the components. For example, any well-known vessel used in the preparation of photoresist raw materials and metal complexes may be used. The vessel may or may not have a lid and may or may not be closed. The material of which the vessel is made is not particularly limited. The size of the vessel is not particularly limited. For example, the vessel may be of such size as used in ordinary laboratories or in industrial manufacture. The vessel may have an ability to carry out such operation as heating, pressurizing or stirring on the components. For example, a reaction vessel, reactor, kettle or tank (e.g., stirred tank) may be used. Inter alia, a stirred tank is preferably used for mixing the components.

In step (i), it is not critical how to introduce the components into the vessel. In one exemplary method, the components are admitted into the vessel through an inlet port.

When the components are fed, they may be admitted successively or all at once. When one component is fed, it may be admitted in divided portions. When the components are successively admitted into the vessel, the order of admission is not particularly limited.

In step (i), the atmosphere within the vessel is not particularly limited. The vessel interior may be filled with air or another gas such as nitrogen or argon. The vessel may be kept under atmospheric, sub-atmospheric or added pressure.

In step (i), it is not critical how to mix the components. Preferably the components are mixed by stirring. In stirring for mixing, an impeller or magnetic stirrer may be used. The size and material of the impeller or stirrer chips are not particularly limited. The rotational speed of stirring is preferably 20 to 500 rpm, more preferably 40 to 350 rpm, even more preferably 50 to 300 rpm though not critical. In the case of stirring for mixing, stirring may be started before any component is admitted or after at least one component is admitted.

The mixing time of step (i), though not critical, is preferably at least 30 minutes, more preferably at least 1 hour, even more preferably at least 2 hours, further preferably at least 4 hours, most preferably at least 6 hours. The upper limit of mixing time, though not critical, is preferably up to 24 hours, more preferably up to 18 hours, even more preferably up to 12 hours in view of productivity.

The temperature of mixing step (or the temperature of components within the vessel), though not critical, is preferably −80 °C to 300 °C, more preferably 0 °C to 100 °C, even preferably 15 °C to 70 °C, most preferably 20 °C to 60 °C. During mixing, the temperature of the components in the vessel is desirably kept constant, preferably within ±10 °C, more preferably within ±5 °C, even more preferably within ±1 °C from the preset temperature.

During mixing, the components in the vessel may be ultrasonified.

### Step (ii)

Step (ii) is to filter insolubles out of the mixture of step (i) to remove at least part of the impurity in the raw metal complex.

The filtration unit used herein, through not particularly limited, may be any well-known filtration unit used in the preparation of photoresist raw materials and metal complexes. The filtration unit may be composed of a container, funnel, filter medium and the like. When the filtration unit includes a container, the container may or may not have a lid and may or may not be closed as long as it can accommodate the reaction solution or filtrate. The material of which the container is made is not particularly limited. The size of the container is not particularly limited. For example, the container may be of such size as used in ordinary laboratories or in industrial manufacture. The container may have an ability to carry out such operation as heating, pressurizing or stirring on the components. For example, a reaction vessel, reactor, kettle or tank (e.g., stirred tank) may be used. When the filtration unit includes a funnel, the material of which the funnel is made is not particularly limited. The size of the funnel is not particularly limited. For example, the funnel may be of such size as used in ordinary laboratories or in industrial manufacture. When the filtration unit includes a filter medium, the material and form of the medium are not particularly limited. For example, a filter of paper (paper filter), resin, celite, silica gel, activated carbon, or a mixture thereof may be used. The amount of the filter medium used is not particularly limited and may be an amount used in ordinary laboratories or in industrial manufacture. The filtration unit may have an ability to increase or reduce the internal pressure for more efficient filtration.

In step (ii), it is not critical how to perform filtration. For example, the mixture may be filtered all at once or in divided portions. Such operation as decantation may be previously performed to reduce the amount of insolubles. The filtration may be performed once or plural times.

In step (ii), the atmosphere within the filtration unit is not particularly limited. The filtration unit interior may be filled with air or another gas such as nitrogen or argon. The filtration unit may be kept under atmospheric, sub-atmospheric or added pressure.

The filtration time of step (ii), though not critical, is preferably at least 1 second, more preferably at least 10 seconds, even more preferably at least 1 minute, most preferably at least 5 minutes. The upper limit of filtration time, though not critical, is preferably up to 24 hours, more preferably up to 18 hours, even more preferably up to 12 hours in view of productivity.

The temperature during filtration (i.e., the temperature of the mixture), though not critical, is preferably −80 °C to 300 °C, more preferably 0 °C to 100 °C, even preferably 15 °C to 35 °C, most preferably 20 °C to 25 °C.

The insolubles collected in step (ii) and the filter medium used in step (ii) may be cleaned with a solvent. The cleaning solvent is not particularly limited as long as it is an organic solvent. Exemplary organic solvents include hydrocarbons such as pentane, hexane, octane, cyclopentane, and cyclohexane; ketones such as cyclohexanone and methyl-2-n-pentyl ketone; alcohols such as 3-methoxybutanol, 3-methyl-3-methoxybutanol, 1-methoxy-2-propanol, 1-ethoxy-2-propanol, and diacetone alcohol; ethers such as isopropyl ether, propylene glycol monomethyl ether, ethylene glycol monomethyl ether, propylene glycol monoethyl ether, ethylene glycol monoethyl ether, propylene glycol dimethyl ether, diethylene glycol dimethyl ether, diethyl ether, tetrahydrofuran, and dioxane; esters such as propylene glycol monomethyl ether acetate, propylene glycol monoethyl ether acetate, ethyl lactate, ethyl pyruvate, butyl acetate, methyl 3-methoxypropionate, ethyl 3-ethoxypropionate, methyl 2-hydroxyisobutyrate, tert-butyl acetate, cyclohexyl acetate, tert-butyl propionate, and propylene glycol mono-tert-butyl ether acetate; lactones such as γ-butyrolactone; carboxylic acids such as acetic acid and propionic acid; aromatic solvents such as benzene, toluene, xylene, cresol, anisole, and benzotrifluoride; halogenated hydrocarbons such as dichloromethane, chloroform, and carbon tetrachloride; and mixtures thereof. The solution as cleaned may or may not be added to the filtrate of step (ii), and is preferably added to the filtrate to increase the yield.

Step (iii)

After step (ii), the method of the invention may include the step (iii) of isolating the product.

It is not critical how to isolate the product. Any well-known isolation means used in the preparation of photoresist raw materials and metal complexes may be used.

For example, step (iii) of isolating the product may include a separatory step for removing water and water-soluble components.

The separation unit used in the separatory step is not particularly limited and any well-known separation unit used in the preparation of photoresist raw materials and metal complexes may be used. For example, a separatory funnel may be used. The material of which the separation unit is made is not particularly limited. The size of the separation unit is not particularly limited. For example, the separation unit may be of such size as used in ordinary laboratories or in industrial manufacture. The separation unit may have an ability to carry out such operation as heating, cooling, pressurizing, depressurizing or stirring on the contents.

The separation method used in the separatory step is not particularly limited and any well-known separation method used in the preparation of photoresist raw materials and metal complexes may be used. In the separatory step, the solution may be separated all at once or in divided portions. The solution may be separated after adding water or a solvent thereto or without adding water or a solvent. In the separatory step, the solution in the separation unit may or may not be stirred and mixed.

In the embodiment wherein the solution is stirred and mixed in the separatory step, the stirring/mixing time, though not critical, is preferably at least 1 second, more preferably at least 5 seconds, even more preferably at least 10 seconds, most preferably at least 30 seconds. The upper limit of stirring/mixing time, though not critical, is preferably up to 24 hours, more preferably up to 18 hours, even more preferably up to 12 hours in view of productivity.

The temperature of separation step (or the temperature of the solution), though not critical, is preferably −80 °C to 300 °C, more preferably 0 °C to 100 °C, most preferably 15 °C to 35 °C.

Step (iii) may include a concentration step of removing the solvent.

The concentration unit used in the concentration step is not particularly limited and any well-known concentration unit used in the preparation of photoresist raw materials and metal complexes may be used. For example, an evaporator or distillation unit may be used. The concentration unit is not particularly limited as long as the solution obtained from step (ii) can be concentrated. The material of which the concentration unit is made is not particularly limited. The size of the concentration unit is not particularly limited. For example, the concentration unit may be of such size as used in ordinary laboratories or in industrial manufacture. The concentration unit may have an ability to carry out such operation as heating, cooling, pressurizing, depressurizing or stirring on the contents.

The concentration method used in the concentration step is not particularly limited. For example, the solution may be concentrated all at once or in divided portions. The concentration unit may be under atmospheric, sub-atmospheric or added pressure.

The concentration time, though not critical, is preferably at least 1 minute, more preferably at least 5 minutes, even more preferably at least 10 minutes. The upper limit of concentration time, though not critical, is preferably up to 24 hours, more preferably up to 18 hours, even more preferably up to 12 hours in view of productivity.

The temperature of concentration step (or the temperature of the solution), though not critical, is preferably −80 °C to 300 °C, more preferably 0 °C to 100 °C.

In the step of concentrating the solution, concentration may be continued until the solvent is removed in its entirety or to an intermediate point when some solvent still remains.

Step (iii) may include the step of adding a poor solvent to the solution and allowing the product to crystalize.

In the step of adding a poor solvent for crystallization, the poor solvent may be any of organic solvents. Exemplary organic solvents include hydrocarbons such as pentane, hexane, octane, cyclopentane, and cyclohexane; ketones such as cyclohexanone and methyl-2-n-pentyl ketone; alcohols such as 3-methoxybutanol, 3-methyl-3-methoxybutanol, 1-methoxy-2-propanol, 1-ethoxy-2-propanol, and diacetone alcohol; ethers such as isopropyl ether, propylene glycol monomethyl ether, ethylene glycol monomethyl ether, propylene glycol monoethyl ether, ethylene glycol monoethyl ether, propylene glycol dimethyl ether, diethylene glycol dimethyl ether, diethyl ether, tetrahydrofuran, and dioxane; esters such as propylene glycol monomethyl ether acetate, propylene glycol monoethyl ether acetate, ethyl lactate, ethyl pyruvate, butyl acetate, methyl 3-methoxypropionate, ethyl 3-ethoxypropionate, methyl 2-hydroxyisobutyrate, tert-butyl acetate, cyclohexyl acetate, tert-butyl propionate, and propylene glycol mono-tert-butyl ether acetate; lactones such as γ-butyrolactone; carboxylic acids such as acetic acid and propionic acid; aromatic solvents such as benzene, toluene, xylene, cresol, anisole, and benzotrifluoride; halogenated hydrocarbons such as dichloromethane, chloroform, and carbon tetrachloride; and mixtures thereof.

Step (iii) may include the step of lowering the temperature of the solution for helping the product crystalize.

In the step of lowering the temperature of the solution for crystallization, the temperature of the solution, though not critical, is preferably −80 °C to 100 °C, more preferably −80 °C to 50 °C, even more preferably −80 °C to 30 °C, most preferably −80 °C to 0 °C.

Step (iii) may include the step of recovering the crystallized product by filtration.

The filtration unit and method used in the recovery step are not particularly limited. For example, the filtration unit and method used in step (ii) may be used.

Step (iii) may include the step of purifying the recovered product.

The method used in the purifying step is not particularly limited, and any well-known methods used in the purification of photoresist raw materials and metal complexes may be used. For example, a well-known method such as chromatography, distillation, sublimation, or re-crystallization may be used.

The high-purity metal complex obtained by the inventive method is not particularly limited as long as it is composed of metal atoms and ligands of at least two types and has a high ratio of one ligand as compared with the raw metal complex.

The high-purity metal complex is preferably a zinc tetranuclear cluster having formula (1) in which the content of ligand (1b) based on the overall ligands is reduced from that in the raw metal complex. The content of ligand (1b), though not critical, is preferably up to 99 mol %, more preferably up to 50 mol %, even more preferably up to 20 mol %, further preferably up to 10 mol %, most preferably up to 5 mol % based on the overall ligands.

### [High-Purity Metal Complex]

Another embodiment of the invention is a high-purity metal complex which is a zinc tetranuclear cluster having formula (1) in which the content of ligand (1b) is up to 5 mol % based on the overall ligands. The high-purity metal complex has high storage stability in the ambient atmosphere because of full or substantial elimination of a metal complex having moisture-sensitive ligand (1b).

The high-purity metal complex may be obtained from the inventive method or another method. The high-purity metal complex obtained from the inventive method is preferred because a metal complex having moisture-sensitive ligand (1b) can be selectively and efficiently removed.

### [Resist Composition]

A further embodiment of the invention is a resist composition comprising the high-purity metal complex and an organic solvent.

When isomers exist in the high-purity metal complex due to the arrangement of ligands, a mixture of isomers or a single isomer may be used. When the metal complex is composed of ligands of two or more different types, either a single metal complex in which the ratio of ligands is completely controlled or a mixture of metal complexes in which the ratio of ligands is different may be used.

The metal complex may be used alone or in admixture of two or more.

### [Organic Solvent]

The resist composition contains an organic solvent. The organic solvent is not particularly limited as long as the metal complex is dissolvable therein and film formation is possible. Exemplary organic solvents include hydrocarbons such as pentane, hexane, octane, cyclopentane, and cyclohexane; ketones such as cyclohexanone and methyl-2-n-pentyl ketone; alcohols such as 3-methoxybutanol, 3-methyl-3-methoxybutanol, 1-methoxy-2-propanol, 1-ethoxy-2-propanol, and diacetone alcohol; ethers such as isopropyl ether, propylene glycol monomethyl ether, ethylene glycol monomethyl ether, propylene glycol monoethyl ether, ethylene glycol monoethyl ether, propylene glycol dimethyl ether, diethylene glycol dimethyl ether, diethyl ether, tetrahydrofuran, and dioxane; esters such as propylene glycol monomethyl ether acetate, propylene glycol monoethyl ether acetate, ethyl lactate, ethyl pyruvate, butyl acetate, methyl 3-methoxypropionate, ethyl 3-ethoxypropionate, methyl 2-hydroxyisobutyrate, tert-butyl acetate, cyclohexyl acetate, tert-butyl propionate, and propylene glycol mono-tert-butyl ether acetate; lactones such as γ-butyrolactone; carboxylic acids such as acetic acid and propionic acid; aromatic solvents such as benzene, toluene, xylene, cresol, anisole, and benzotrifluoride; halogenated hydrocarbons such as dichloromethane, chloroform, and carbon tetrachloride; and mixtures thereof.

The amount of the organic solvent is preferably 200 to 20,000 parts by weight, more preferably 500 to 15,000 parts by weight per 100 parts by weight of the metal complex.

It is believed that the resist composition is such that photo-decomposition of the metal complex as the major component and subsequent agglomeration or crosslinking reaction of partially broken metal complexes cause a change of development resistance in exposed and unexposed regions, whereby a contrast is manifested. Since this reaction is not a catalytic reaction, the resist composition functions as a non-chemically amplified resist composition. This enables resolution even in small-size regions which are difficult to pattern in prior art chemically amplified resist compositions based on a multi-component polymer. Particularly in the EUV lithography, the resist composition is improved in stochastics because the metal atoms have high EUV absorptivity and exhibits high sensitivity and reduced LWR. The high-purity metal complex has high storage stability in the ambient atmosphere because of full or substantial elimination of a metal complex having moisture-sensitive ligand. Because of high purity, the metal complex has little difference in compositional ratio between batches. The resist composition is thus improved in reproducibility of lithography.

### [Photoacid Generator]

In addition to the high-purity metal complex and the organic solvent, the resist composition may comprise another component, typically a photoacid generator (PAG). Since the PAG generates an acid in the exposed region, the effect of promoting crosslinking reaction of the metal complex is expected. The PAG used herein is not particularly limited as long as it generates an acid upon exposure to high-energy radiation. Any of PAGs used in prior art chemically amplified resist compositions may be used. PAGs capable of generating sulfonic acids, imide acids and methide acids are suitable. The preferred PAGs include sulfonium salt, iodonium salt, sulfonyl diazomethane, N-sulfonyloxyimide, and oxime-O-sulfonate acid generators. Examples thereof are described in JP-A 2008-111103, paragraphs [0122]-[0142] and JP-A 2022-163697, paragraphs [0127]-[0193].

When the resist composition contains a PAG, the amount thereof is preferably 0.01 to 20% by weight based on the overall solids. The term solids generally refers to all components in the resist composition exclusive of the solvent. The PAG may be used alone or in admixture.

### [Radical Scavenger]

The resist composition may comprise a radical scavenger as the other component. The radical scavenger enables to control photo-reaction and adjust sensitivity in the photolithography.

Suitable radical scavengers include hindered phenol compounds, quinone compounds, hindered amine compounds, and thiol compounds. Exemplary hindered phenol compounds include dibutylhydroxytoluene (BHT) and 2,2′-methylenebis(4-methyl-6-tert-butylphenol). Exemplary quinone compounds include 4-methoxyphenol (or hydroquinone monomethyl ether) and hydroquinone. Exemplary hindered amine compounds include 2,2,6,6-tetramethylpiperidine and 2,2,6,6-tetramethylpiperidine-N-oxy radical. Exemplary thiol compounds include dodecanethiol and hexadecanethiol.

When the resist composition contains a radical scavenger, the amount thereof is preferably 0.01 to 10% by weight based on the overall solids. The radical scavenger may be used alone or in admixture.

### [Surfactant]

The resist composition may comprise a surfactant as the other component. For the surfactant, reference should be made to those compounds described in JP-A 2010-215608 and JP-A 2011-016746. Among others, surfactants FC-4430 (3M), Olfine® E1004 (Nissin Chemical Co., Ltd.), Surflon® 5-381, KH-20 and KH-30 (AGC Seimi Chemical Co., Ltd.) are preferred. Partially fluorinated oxetane ring-opened polymers having the formula (surf-1) are also useful.

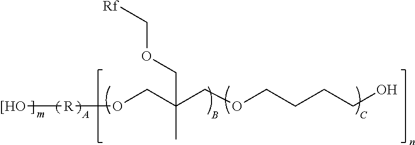

In formula (surf-1), R is a di- to tetra-valent C₂-C₅ aliphatic group. Exemplary divalent aliphatic groups include ethylene, 1,4-butylene, 1,2-propylene, 2,2-dimethyl-1,3-propylene and 1,5-pentylene. Exemplary tri- and tetra-valent groups are shown below.

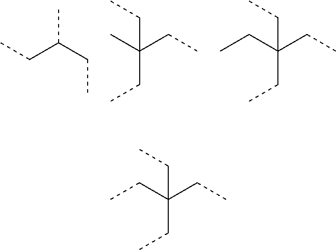

Herein the broken line denotes a valence bond. These formulae are partial structures derived from glycerol, trimethylol ethane, trimethylol propane, and pentaerythritol, respectively. Of these, 1,4-butylene and 2,2-dimethyl-1,3-propylene are preferably used.

Rf is trifluoromethyl or pentafluoroethyl, and preferably trifluoromethyl. The letter m is an integer of 0 to 3, n is an integer of 1 to 4, and the sum of m and n, which represents the valence of R, is an integer of 2 to 4. “A” is equal to 1, B is an integer of 2 to 25, and C is an integer of 0 to 10. Preferably, B is an integer of 4 to 20, and C is 0 or 1. Note that the formula (surf-1) does not prescribe the arrangement of respective constituent units while they may be arranged either blockwise or randomly. For the preparation of surfactants in the form of partially fluorinated oxetane ring-opened polymers, reference should be made to U.S. Pat. No. 5,650,483, for example.

When the resist composition contains a surfactant, the amount thereof is preferably 0.001 to 20 parts by weight, more preferably 0.1 to 10 parts by weight per 100 parts by weight of the metal complex. The surfactant may be used alone or in admixture.

### [Laminate]

A further embodiment of the invention is a laminate comprising a substrate and a resist film formed on the substrate from the resist composition defined above.

The laminate is advantageous in that a resist film obtained from the resist composition has a high sensitivity and improved maximum resolution, is effective for precise small-size processing, and is improved in post-PEB delay (PPD) (that is, the lapse of time from PEB to development). The laminate finds a wide variety of applications and is quite useful in the resist processing technology.

The laminate may further comprise a resist underlying film between the substrate and the resist film, if necessary.

The resist film is not particularly limited as long as it is formed from the resist composition defined herein. For example, the resist film may be a film consisting of the metal complex or a film in which at least a part of the metal complex is the product of the metal complex reacting with other substances (e.g., water, oxygen and solvent) during bake or in the environment.

### [Pattern Forming Process]

A still further embodiment of the invention is a process for forming a pattern, comprising the steps of applying the resist composition defined above onto a substrate (or onto an underlying film on a substrate) to form a resist film, exposing the resist film to high-energy radiation, and developing the exposed resist film in a developer to form a resist pattern.

The substrate used herein may be a substrate for integrated circuitry fabrication, e.g., Si, SiO₂, SiN, SiON, TiN, WSi, BPSG, SOG, organic antireflective film, etc. or a substrate for mask circuitry fabrication, e.g., Cr, CrO, CrON, MoSi₂, SiO₂, etc.

The resist composition is applied onto the substrate or the resist underlying film on the substrate by a suitable coating technique such as spin coating, roll coating, flow coating, dip coating, spray coating or doctor coating. The coating is prebaked on a hot plate preferably at a temperature of 60 to 200 °C for 10 seconds to 30 minutes, more preferably at 80 to 180 °C for 30 seconds to 20 minutes. The resulting resist film preferably has a thickness of 0.01 to 2 μm. It is noted that the resist underlying film refers to a film formed between the substrate and the resist film in the multilayer resist process. Any of well-known films may be used as the underlying film.

Then the resist film is exposed to a pattern of high-energy radiation. Examples of the high-energy radiation include UV (e.g., g-line of 436 nm, h-line of 405 nm, and i-line of 365 nm), deep UV, EB, EUV of 13.5 nm, BEUV of 2 to 10 nm, X ray, soft X ray, excimer laser (e.g., KrF or ArF excimer laser), γ-ray, and synchrotron radiation. Of these, i-line, KrF excimer laser, ArF excimer laser, EB and EUV are preferred. On use of UV, deep UV, EUV, BEUV, X-ray, soft X-ray, excimer laser, γ-ray or synchrotron radiation, the resist film is exposed directly or through a mask having the desired pattern, preferably in a dose of about 1 to 300 mJ/cm², more preferably 10 to 200 mJ/cm². On use of EB, a pattern may be written directly or through a mask having the desired pattern, preferably in a dose of about 0.1 to 2,000 μC/cm², more preferably 0.5 to 1,500 μC/cm². The resist composition is suited in small-size patterning particularly with EB, EUV or BEUV.

Post-exposure bake (PEB) may be performed in order to promote or complete the reaction after photo-decomposition. That is, after the exposure, the resist film is baked on a hotplate or in an oven, preferably at a temperature of 30 to 200 °C for 10 seconds to 30 minutes, more preferably at 60 to 180 °C for 30 seconds to 20 minutes.

After the exposure or PEB, the resist film is developed. The development mode may be either wet or dry. In the case of wet development, alkaline development or organic solvent development is applicable. In patterning the resist film of the resist composition, organic solvent development is preferred. In the case of wet development, the resist film is developed in a developer, preferably for 3 seconds to 3 minutes, more preferably 5 seconds to 2 minutes by a conventional technique such as dip, puddle or spray technique. Since the resist composition is of negative tone, the exposed region of the resist film is insolubilized and the unexposed region is dissolved in the developer.

The organic solvent used as the developer is preferably selected from 2-octanone, 2-nonanone, 2-heptanone, 3-heptanone, 4-heptanone, 2-hexanone, 3-hexanone, diisobutyl ketone, methylcyclohexanone, acetophenone, methylacetophenone, propyl acetate, butyl acetate, isobutyl acetate, pentyl acetate, butenyl acetate, isopentyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, ethyl phenylacetate, benzyl formate, phenylethyl formate, methyl 3-phenylpropionate, benzyl propionate, 2-phenylethyl acetate, dichloromethane, chloroform, carbon tetrachloride, formic acid, acetic acid, and propionic acid. These organic solvents may be used alone or in admixture of two or more.

The development may be followed by rinsing, if necessary. As the rinse fluid, a solvent which is miscible with the developer and does not dissolve the resist film is preferred. Specifically, alcohol solvents of 3 to 10 carbon atoms, ether solvents of 8 to 12 carbon atoms, alkanes, alkenes, and alkynes of 6 to 12 carbon atoms and aromatic solvents are preferred.

Specifically, suitable alcohols of 3 to 10 carbon atoms include n-propyl alcohol, isopropyl alcohol, 1-butyl alcohol, 2-butyl alcohol, isobutyl alcohol, tert-butyl alcohol, 1-pentanol, 2-pentanol, 3-pentanol, tert-pentyl alcohol, neopentyl alcohol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2-ethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, cyclohexanol, and 1-octanol. Suitable ether compounds of 8 to 12 carbon atoms include di-n-butyl ether, diisobutyl ether, di-sec-butyl ether, di-n-pentyl ether, diisopentyl ether, di-sec-pentyl ether, di-tert-pentyl ether, and di-n-hexyl ether. Suitable alkanes of 6 to 12 carbon atoms include hexane, heptane, octane, nonane, decane, undecane, dodecane, methylcyclopentane, dimethylcyclopentane, cyclohexane, methylcyclohexane, dimethylcyclohexane, cycloheptane, cyclooctane, and cyclononane. Suitable alkenes of 6 to 12 carbon atoms include hexene, heptene, octene, cyclohexene, methylcyclohexene, dimethylcyclohexene, cycloheptene, and cyclooctene. Suitable alkynes of 6 to 12 carbon atoms include hexyne, heptyne, and octyne. Suitable aromatic solvents include toluene, xylene, ethylbenzene, isopropylbenzene, tert-butylbenzene and mesitylene.

Rinsing is effective for minimizing the risks of resist pattern collapse and defect formation. However, rinsing is not essential. If rinsing is omitted, the amount of solvent used may be reduced.

In the development step of the pattern forming process, dry development is also applicable. The dry development is to remove the exposed or unexposed region of the resist film by gas etching, without using the developer. In the practice of the invention, the unexposed region of the resist film is removed with etchant gas to form the desired pattern. For dry etching, a gas mixture containing an etchant such as oxygen, hydrogen, ammonia or halogen and a dilute gas such as nitrogen, helium, argon, carbon dioxide or carbon monoxide is preferably used.

### EXAMPLES

Examples and Comparative Examples are given below by way of illustration and not by way of limitation. The abbreviation “pbw” is parts by weight.

### [1] Preparation of Raw Metal Complex

### Example 1-1

### Preparation of Raw Metal Complex IM-1

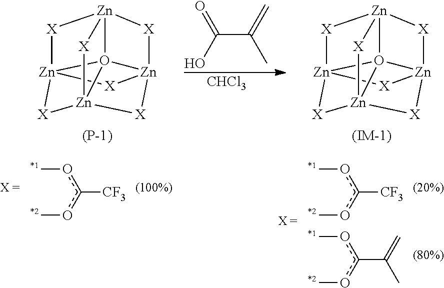

In 480 ml of chloroform, 15 g of ZnTAC24® (P-1), which is commercially available from Takasago International Corp., and 16.2 g of methacrylic acid were dissolved. Reaction was effected at 60 °C for 6 hours. On an evaporator, the solvent was distilled off under reduced pressure. By the subsequent azeotropic distillation with toluene, 30 g of an oily crude product was obtained. A mixture of 70 ml/30 ml isopropyl ether/hexane was added to the oily crude product, obtaining 8 g of raw metal complex IM-1 in powder form (yield 62%). The ratio of ligands was determined by NMR spectroscopy using 2,3,5,6-tetrafluoro-p-xylene as the internal standard, finding 20 mol % of trifluoroacetic acid ligand and 80 mol % of methacrylic acid ligand.

### Example 1-2

### Preparation of Raw Metal Complex IM-2

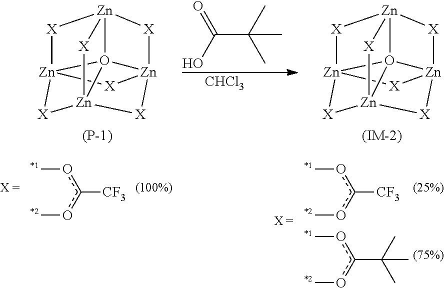

By the same procedure as in Example 1-1 except that pivalic acid was used instead of methacrylic acid, 9 g of raw metal complex IM-2 in powder form was obtained (yield 64%). The ratio of ligands was determined by NMR spectroscopy using 2,3,5,6-tetrafluoro-p-xylene as the internal standard, finding 25 mol % of trifluoroacetic acid ligand and 75 mol % of pivalic acid ligand.

### Example 1-3

### Preparation of Raw Metal Complex IM-3

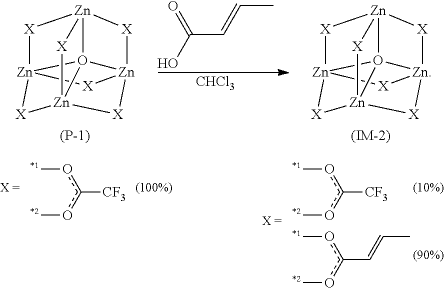

By the same procedure as in Example 1-1 except that crotonic acid was used instead of methacrylic acid, 8 g of raw metal complex IM-3 in powder form was obtained (yield 63%). The ratio of ligands was determined by NMR spectroscopy using 2,3,5,6-tetrafluoro-p-xylene as the internal standard, finding 10 mol % of trifluoroacetic acid ligand and 90 mol % of crotonic acid ligand.

### [2] Preparation of High-Purity Metal Complex

### Example 2-1

### Preparation of High-Purity Metal Complex Z-1

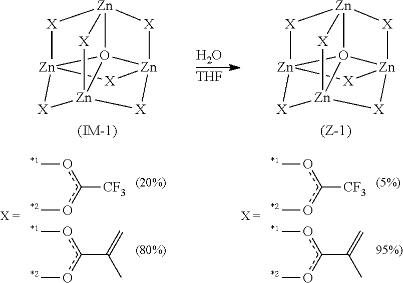

Raw metal complex IM-1, 8 g, was dissolved in 400 g of tetrahydrofuran (THF). 5.3 g of pure water was added to the solution, which was stirred at room temperature for 6 hours. The insolubles formed during stirring was removed by filtration. On an evaporator, the solvent in the filtrate was evaporated off under reduced pressure, obtaining 12 g of an oily crude product. 50 ml of hexane was added to the oily crude product, obtaining 5.4 g of high-purity metal complex Z-1 (yield 68%). The ratio of ligands was determined by NMR spectroscopy using 2,3,5,6-tetrafluoro-p-xylene as the internal standard, finding 5 mol % of trifluoroacetic acid ligand and 95 mol % of methacrylic acid ligand.

¹H-NMR (CDCl₃, 500 MHz): δ=1.93 (dd, J=1.5, 1.0 Hz, 3H, CH₂=C—CH₃), 5.56 (q, J=1.5 Hz, 1H, ═CH₂), 6.20 (q, J=1.0 Hz, 1H, ═CH₂)

¹⁹F-NMR (CDCl₃, 470 MHz): δ=−76.5 (s, 1F, —CF₃)

### Example 2-2

### Preparation of High-Purity Metal Complex Z-2

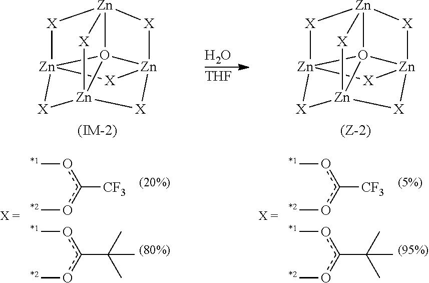

By the same procedure as in Example 2-1 except that raw metal complex IM-2 was used instead of raw metal complex IM-1, 7.4 g of high-purity metal complex Z-2 in powder form was obtained (yield 93%). The ratio of ligands was determined by NMR spectroscopy using 2,3,5,6-tetrafluoro-p-xylene as the internal standard, finding 5 mol % of trifluoroacetic acid ligand and 95 mol % of pivalic acid ligand.

¹H-NMR (DMSO-d6, 500 MHz): δ=1.07 (s, 9H, —C(CH₃)₃)

¹⁹F-NMR (DMSO-d6, 470 MHz): δ=−76.5 (s, 1F, —CF₃)

### Example 2-3

### Preparation of High-Purity Metal Complex Z-3

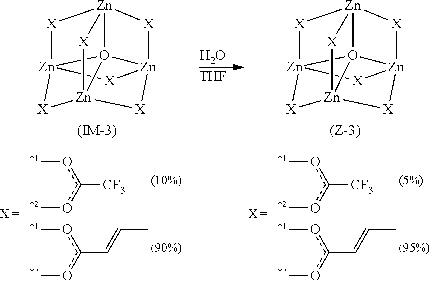

By the same procedure as in Example 2-1 except that raw metal complex IM-3 was used instead of raw metal complex IM-1, 6.5 g of high-purity metal complex Z-3 in powder form was obtained (yield 81%). The ratio of ligands was determined by NMR spectroscopy using 2,3,5,6-tetrafluoro-p-xylene as the internal standard, finding 5 mol % of trifluoroacetic acid ligand and 95 mol % of crotonic acid ligand.

¹H-NMR (CDCl₃, 500 MHz): δ=1.84 (dd, J=7.0, 2.0 Hz, 3H, —CH═CH—CH₃), 5.85 (dq, J=15.0, 2.0 Hz, 1H, —CH═CH—CH₃), 7.01 (dq, J=15.0, 7.0 Hz, 1H, —CH═CH—CH₃)

¹⁹F-NMR (CDCl₃, 470 MHz): δ=−76.5 (s, 1F, —CF₃)

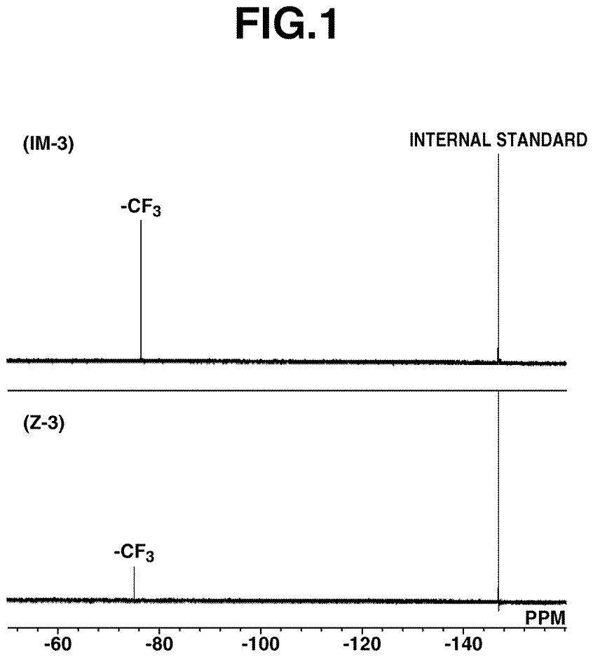

FIG. 1 shows the peak intensity on ¹⁹F-NMR analysis of —CF₃ group in raw metal complex IM-3 and high-purity metal complex Z-3. It is demonstrated that the inventive method is successful in preparing a high-purity metal complex having a reduced ratio of trifluoroacetic acid ligand as compared with a raw metal complex.

### [3] Preparation of Resist Composition

### Examples 3-1 to 3-5 and Comparative Examples 3-1 to 3-3

Each of resist compositions R-1 to R-5 and comparative resist compositions CR-1 to CR-3 was prepared by dissolving selected components in a solvent according to the formulation shown in Table 1, and passing the solution through a Teflon® filter having a pore size of 0.2 μm.

TABLE 1

| | | Resist | Component A | Component B | Component C | Solvent |
|---|---|---|---|---|---|---|
| | | composition | (pbw) | (pbw) | (pbw) | (pbw) |
| Example | 3-1 | R-1 | Z-1 (20.0) | — | — | PGEE (1000) |
| | 3-2 | R-2 | Z-2 (20.0) | — | — | PGEE (1000) |
| | 3-3 | R-3 | Z-3 (20.0) | — | — | PGEE (1000) |
| | 3-4 | R-4 | Z-1 (20.0) | P-1 (19) | — | PGEE (1000) |
| | 3-5 | R-5 | Z-2 (20.0) | — | Sc-1 (0.01) | PGEE (1000) |
| Comparative | 3-1 | CR-1 | IM-1 (20.0) | — | — | PGEE (1000) |
| Example | 3-2 | CR-2 | IM-2 (20.0) | — | — | PGEE (1000) |
| | 3-3 | CR-3 | IM-3 (20.0) | — | — | PGEE (1000) |

In Table 1, components A, B and C are a metal complex, photoacid generator, and radical scavenger, respectively. The structure of metal complexes Z-1 to Z-3 as component A is as shown above. Components B and C are identified below.
P-1: triphenylsulfonium tosylate
Sc-1: dibutylhydroxytoluene
PGEE: 1-ethoxy-2-propanol

### [4] EB Lithography Test

### Examples 4-1 to 4-5 and Comparative Examples 4-1 to 4-3

Each of the resist compositions (R-1 to R-5 and CR-1 to CR-3) was spin coated on a silicon substrate having an antireflective film of 60 nm thick (DUV-42 by Nissan Chemical Corp.) and prebaked on a hotplate at 100 °C for 60 seconds to form a resist film of 40 nm thick. Using an electron beam lithography system ELS-F125 (Elionix Inc., accelerating voltage 125 kV), the resist film was exposed to EB. The resist film was baked (PEB) on a hotplate at the temperature shown in Table 2 for 60 seconds and developed in a 95:5 mixture of propylene glycol monoethyl ether acetate. acetic acid for 30 seconds to form a pattern. Specifically a line-and-space (LS) pattern of negative tone having a space width of 20 nm and a pitch of 40 nm was formed.

The LS pattern was observed under CD-SEM (CG-5000 or CG-6300, Hitachi High-Technologies Corp.) and evaluated for sensitivity, LWR, maximum resolution, and PED by the following methods. The results are shown in Table 2.

### [Evaluation of Sensitivity]

The optimum dose (Eop, μC/cm²) which provided a LS pattern with a space width of 20 nm and a pitch of 40 nm was determined and reported as sensitivity.

### [Evaluation of LWR]

A LS pattern was formed by exposure in the optimum dose (Eop). The space width was measured at longitudinally spaced apart 10 points, from which a 3-fold value (36) of the standard deviation (6) was determined and reported as LWR. A smaller value indicates a pattern having a lower roughness and more uniform space width.

### [Evaluation of Maximum Resolution]

A LS pattern was formed while increasing the exposure dose little by little from the optimum dose (Eop). The line width (nm) which could be resolved was determined and reported as maximum resolution. A smaller value indicates a pattern having a better maximum resolution and smaller feature size.

### [Evaluation of PPD Stability]

After exposure at the optimum dose, PEB and development were performed under the above-mentioned conditions. A wafer in which a pattern was formed by development without any delay after PEB is designated PPD0h. A wafer in which a pattern was formed by development at a delay of 6 hours after PEB is designated PPD6h. The line width of these wafers was measured under CD-SEM (CG-6300). A change (APPD) of line width (CD) by PPD was determined. The results are shown in Table 2.

TABLE 2

| | | | | | | Maximum | PPD 0 h | PPD 6 h | ΔPPD |
|---|---|---|---|---|---|---|---|---|---|
| | | Resist | PEB | Eop | LWR | resolution | CD | CD | CD |
| | | composition | (°C) | (μC/cm²) | (nm) | (nm) | (nm) | (nm) | (nm) |
| Example | 4-1 | R-1 | 90 | 500 | 3.1 | 13.1 | 19.9 | 20.0 | 0.1 |
| | 4-2 | R-2 | No | 1,100 | 3.0 | 13.0 | 20.0 | 20.2 | 0.2 |
| | 4-3 | R-3 | 90 | 1,350 | 3.2 | 12.4 | 20.3 | 20.4 | 0.1 |
| | 4-4 | R-4 | 90 | 300 | 3.2 | 12.5 | 20.1 | 20.4 | 0.3 |
| | 4-5 | R-5 | 90 | 900 | 3.3 | 12.0 | 20.0 | 20.0 | 0.0 |
| Comparative | 4-1 | CR-1 | 90 | 3,200 | 4.7 | 19.9 | 20.1 | 25.3 | 5.2 |
| Example | 4-2 | CR-2 | No | 5,000 | 4.9 | 20.1 | 20.0 | 25.5 | 5.5 |
| | 4-3 | CR-3 | 90 | 10,000 | 5.2 | 19.8 | 20.2 | 26.3 | 6.1 |

As is evident from Table 2, the resist compositions within the scope of the invention show excellent LWR and maximum resolution in forming negative patterns through organic solvent development according to the EB lithography. The change of CD by PPD is small, indicating that the resist film is stable after pattern formation. Since the resist compositions contain a high density of zinc atoms having a high EUV absorptivity, a remarkably high sensitivity in the EUV lithography is expectable.

### [5] Evaluation of Storage Stability

### Examples 5-1 to 5-5 and Comparative Examples 5-1 to 5-3

The resist compositions (R-1 to R-5 and CR-1 to CR-3) were held at normal temperature (20±5 °C) for a certain period, after which they were visually observed to examine whether or not precipitates formed. The composition in which no precipitates formed on storage for more than 6 months is rated “Pass” (◯). The composition in which precipitates formed on storage for less than 6 months is rated “Reject”. (x) The results are shown in Table 3.

TABLE 3

| | | Resist composition | Storage stability |
|---|---|---|---|
| Example | 5-1 | R-1 | ◯ |
| | 5-2 | R-2 | ◯ |
| | 5-3 | R-3 | ◯ |
| | 5-4 | R-4 | ◯ |
| | 5-5 | R-5 | ◯ |
| Comparative Example | 5-1 | CR-1 | X |
| | 5-2 | CR-2 | X |
| | 5-3 | CR-3 | X |

As seen from Table 3, the resist compositions within the scope of the invention are stable during storage and easy to handle.

### [6] Reproducibility Test

### Examples 6-1 to 6-5 and Comparative Examples 6-1 to 6-3

Each of raw metal complexs IM-1 to IM-3 and high-purity metal complexes Z-1 to Z-3 was synthesized twice. The first prepared batch is designated Lot 1. The second prepared batch is designated Lot 2. Using Lots 1 and 2, resist compositions (R-1 to R-5 and CR-1 to CR-3) were prepared and evaluated for sensitivity, LWR, and maximum resolution by the same test as [4] EB lithography test. The results are shown in Table 4.

TABLE 4

| | | | | | | | Maximum |
|---|---|---|---|---|---|---|---|
| | | Resist | | PEB | Eop | LWR | resolution |
| | | composition | Component A | (°C) | (μC/cm²) | (nm) | (nm) |
| Example | 6-1 | R-1 | Z-1 (Lot 1) | 90 | 510 | 3.1 | 13.1 |
| | | | Z-1 (Lot 2) | 90 | 510 | 3.2 | 13.0 |
| | 6-2 | R-2 | Z-2 (Lot 1) | nil | 1,100 | 3.0 | 13.0 |
| | | | Z-2 (Lot 2) | nil | 1,120 | 3.0 | 13.2 |
| | 6-3 | R-3 | Z-3 (Lot 1) | 90 | 1,360 | 3.2 | 12.4 |
| | | | Z-3 (Lot 2) | 90 | 1,350 | 3.2 | 12.6 |
| | 6-4 | R-4 | Z-4 (Lot 1) | 90 | 300 | 3.2 | 12.5 |
| | | | Z-4 (Lot 2) | 90 | 300 | 3.1 | 12.5 |
| | 6-5 | R-5 | Z-5 (Lot 1) | 90 | 900 | 3.3 | 12.0 |
| | | | Z-5 (Lot 2) | 90 | 910 | 3.3 | 12.0 |
| Comparative | 6-1 | CR-1 | IM-1 (Lot 1) | 90 | 3,200 | 4.7 | 19.9 |
| Example | | | IM-1 (Lot 2) | 90 | 3,740 | 5.2 | 25.4 |
| | 6-2 | CR-2 | IM-2 (Lot 1) | nil | 5,000 | 4.9 | 20.1 |
| | | | IM-2 (Lot 2) | nil | 6,500 | 5.6 | 26.1 |
| | 6-3 | CR-3 | IM-3 (Lot 1) | 90 | 10,000 | 5.2 | 19.8 |
| | | | IM-3 (Lot 2) | 90 | 8,000 | 4.7 | 15.2 |

As seen from Table 4, the resist compositions within the scope of the invention show little change between batches and high reproducibility of lithography.

Japanese Patent Application No. 2025-070498 is incorporated herein by reference.

Although some preferred embodiments have been described, many modifications and variations may be made thereto in light of the above teachings. It is therefore to be understood that the invention may be practiced otherwise than as specifically described without departing from the scope of the appended claims.

1. A method for preparing a high-purity metal complex comprising the steps of:
(i) mixing a raw metal complex with water and an organic solvent, the raw metal complex containing an impurity, and
(ii) filtering insolubles out of the mixture of step (i) to remove at least part of the impurity.

2. The method of claim 1 wherein the raw metal complex is a zinc tetranuclear cluster having the formula (1): 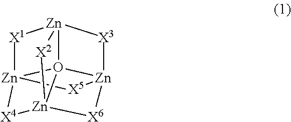
wherein X¹, X², X³, X⁴, X⁵ and X⁶ are each independently a ligand having the formula (1a) or (1b): 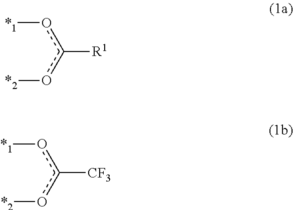
wherein R¹ is hydrogen, carbonyl or a C₁-C₂₀ hydrocarbyl group which may contain a heteroatom, exclusive of trifluoromethyl, *1 and *2 each designate a point of attachment to zinc atom.

3. The method of claim 2 wherein the raw metal complex is a zinc tetranuclear cluster having the formula (1) wherein the content of the ligand having formula (1b) is more than 5 mol % based on the overall ligands.

4. The method of claim 2 wherein the high-purity metal complex is a zinc tetranuclear cluster having the formula (1) wherein the content of the ligand having formula (1b) is not more than 5 mol % based on the overall ligands.

5. A high-purity metal complex which is a zinc tetranuclear cluster having the formula (1): 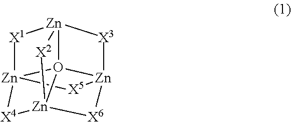
wherein X¹, X², X³, X⁴, X⁵ and X⁶ are each independently a ligand having the formula (1a) or (1b): 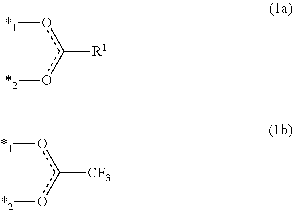
wherein R¹ is hydrogen, carbonyl or a C₁-C₂₀ hydrocarbyl group which may contain a heteroatom, exclusive of trifluoromethyl, *1 and *2 each designate a point of attachment to zinc atom,
wherein the content of the ligand having formula (1b) is not more than 5 mol % based on the overall ligands.

6. A resist composition comprising the high-purity metal complex of claim 5 and a solvent.

7. A laminate comprising a substrate and a resist film formed on the substrate from the resist composition of claim 6.

8. The laminate of claim 7, further comprising a resist underlying film between the substrate and the resist film.

9. A process for forming a pattern, comprising the steps of applying the resist composition of claim 6 onto a substrate to form a resist film, exposing the resist film to high-energy radiation, and developing the exposed resist film to form a resist pattern.

10. The process of claim 9 wherein the high-energy radiation is EB or EUV.
